(19) United States
(12) Patent Application Publication
(10) Pub. No.: US 2022/0069548 A1
(43) Pub. Date: Mar. 3, 2022

(54) SURFACE-EMITTING LASER MEASURING METHOD, MANUFACTURING METHOD, MEASURING APPARATUS, AND NON-TRANSITORY COMPUTER-READABLE MEDIUM

(71) Applicant: SUMITOMO ELECTRIC INDUSTRIES, LTD., Osaka (JP)

(72) Inventor: Ryosuke KUBOTA, Osaka-shi (JP)

(73) Assignee: SUMITOMO ELECTRIC INDUSTRIES, LTD., Osaka (JP)

(21) Appl. No.: 17/371,434

(22) Filed: Jul. 9, 2021

(30) Foreign Application Priority Data
Sep. 2, 2020 (JP) 2020-147379

(51) Int. Cl. H01S 5/42; H01S 5/00

(52) U.S. Cl. CPC H01S 5/423; H01S 5/0042

(57) ABSTRACT

A surface-emitting laser measuring method includes the steps of causing at least one surface-emitting laser to emit light; and measuring a light intensity and a spectrum of the at least one surface-emitting laser by splitting the light emitted from the at least one surface-emitting laser in the step of causing the at least one surface-emitting laser to emit light and causing one split beam to be incident on a light-intensity measuring unit while causing another split beam to be incident on a spectrum measuring unit.

### BACKGROUND OF THE INVENTION

### 1. Field of the Invention

The present disclosure relates to surface-emitting laser measuring methods, manufacturing methods, measuring apparatuses, and non-transitory computer-readable mediums.

This application is based on and claims priority to Japanese Patent Application No. 2020-147379 filed on Sep. 2, 2020, and the entire contents of the Japanese patent application are incorporated herein by reference.

### 2. Description of the Related Art

In a process of manufacturing surface-emitting lasers (vertical-cavity surface-emitting lasers (VCSELs)), a plurality of surface-emitting lasers arranged in an array are caused to emit light for characteristic inspection. There is a technique in which electrical signals with different frequencies are input to a plurality of surface-emitting lasers, and the emitted light is analyzed for each frequency to measure the light intensity (e.g., Japanese Unexamined Patent Application Publication No. 2010-16110).

### SUMMARY OF THE INVENTION

In addition to the light intensity of surface-emitting lasers, the light spectrum may be measured. However, it takes time to sequentially measure the light intensity and the spectrum. Accordingly, an object of the present disclosure is to provide a surface-emitting laser measuring method, manufacturing method, measuring apparatus, and measuring program that allow for a shortened measurement time.

A surface-emitting laser measuring method according to one aspect of the present disclosure includes the steps of causing at least one surface-emitting laser to emit light; and measuring a light intensity and a spectrum of the at least one surface-emitting laser by splitting the light emitted from the at least one surface-emitting laser in the step of causing the at least one surface-emitting laser to emit light and causing one split beam to be incident on a light-intensity measuring unit while causing another split beam to be incident on a spectrum measuring unit.

A surface-emitting laser manufacturing method according to another aspect of the present disclosure includes the steps of forming a plurality of surface-emitting lasers on a wafer; and subjecting the plurality of surface-emitting lasers to the measuring method described above.

A surface-emitting laser measuring apparatus according to another aspect of the present disclosure includes a light-emission causing unit configured to cause at least one surface-emitting laser to emit light; a splitting unit configured to split the light emitted from the at least one surface-emitting laser; a light-intensity measuring unit configured to measure a light intensity of the at least one surface-emitting laser by receiving one split beam from the splitting unit; and a spectrum measuring unit configured to measure a spectrum of the at least one surface-emitting laser by receiving another split beam.

A non-transitory computer-readable medium according to an embodiment of the present disclosure has stored therein a program for causing a computer to execute a process. The process includes the steps of causing at least one surface-emitting laser to emit light; and measuring a light intensity and a spectrum of the at least one surface-emitting laser using the light emitted from the at least one surface-emitting laser in the step of causing the at least one surface-emitting laser to emit light, the light being split and incident on a light-intensity measuring unit and a spectrum measuring unit.

### BRIEF DESCRIPTION OF THE DRAWINGS

FIG. 1A is a schematic view illustrating an example measuring apparatus according to one embodiment.

FIG. 1B is a block diagram illustrating the hardware configuration of a control unit.

FIG. 2 is a plan view illustrating an example wafer.

FIG. 3 is a flowchart illustrating an example surface-emitting laser manufacturing method.

FIG. 4 is a flowchart illustrating an example characteristic measuring method.

FIG. 5A is a schematic view illustrating an example measuring apparatus according to a comparative example.

FIG. 5B is a schematic view illustrating the example measuring apparatus according to the comparative example.

FIG. 6 is a flowchart illustrating an example measuring method in the comparative example.

FIG. 7 is a flowchart illustrating the example measuring method in the comparative example.

### DESCRIPTION OF THE PREFERRED EMBODIMENTS

### Description of Embodiments of the Disclosure

First, embodiments of the present disclosure will be listed and described.

(1) One embodiment of the present disclosure is a surface-emitting laser measuring method including the steps of causing at least one surface-emitting laser to emit light; and measuring a light intensity and a spectrum of the at least one surface-emitting laser by splitting the light emitted from the at least one surface-emitting laser in the step of causing the at least one surface-emitting laser to emit light and causing one split beam to be incident on a light-intensity measuring unit while causing another split beam to be incident on a spectrum measuring unit. Because the light intensity and the spectrum are simultaneously measured, the measurement time can be shortened.

(2) The at least one surface-emitting laser may include a plurality of surface-emitting lasers arranged on a wafer, the plurality of surface-emitting lasers including a first surface-emitting laser and a second surface-emitting laser. After the first surface-emitting laser is subjected to the step of causing light emission and the step of measuring the light intensity and the spectrum, the second surface-emitting laser may be subjected to the step of causing light emission and the step of measuring the light intensity and the spectrum. Because the light intensity and spectrum of a plurality of surface-emitting lasers are simultaneously measured, the measurement time can be further shortened.

(3) The surface-emitting laser measuring method may further include the steps of positioning a splitting unit configured to split the light over the first surface-emitting laser; and after the step of measuring the light intensity and the spectrum of the first surface-emitting laser, positioning the splitting unit over the second surface-emitting laser. The step of measuring the light intensity and the spectrum may include measuring the light intensity and the spectrum by causing one split beam from the splitting unit to be incident on the light-intensity measuring unit while causing another split beam to be incident on the spectrum measuring unit. The time for alignment of the splitting unit and the surface-emitting lasers can be shortened.

(4) The step of causing the at least one surface-emitting laser to emit light may include changing an amplitude of electrical signals input to the at least one surface-emitting laser to cause the at least one surface-emitting laser to emit light for each of the electrical signals with different amplitudes, and the step of measuring the light intensity and the spectrum of the at least one surface-emitting laser may include measuring the light intensity and the spectrum when the amplitude of the electrical signals reaches a predetermined level. Characteristic evaluation in cases where electrical signals are changed can be performed within a short period of time.

(5) Another embodiment of the present disclosure is a surface-emitting laser manufacturing method including the steps of forming a plurality of surface-emitting lasers on a wafer; and subjecting the plurality of surface-emitting lasers to the measuring method described above. The measurement time for the surface-emitting lasers can be shortened during the manufacturing process.

(6) Another embodiment of the present disclosure is a surface-emitting laser measuring apparatus including a light-emission causing unit configured to cause at least one surface-emitting laser to emit light; a splitting unit configured to split the light emitted from the at least one surface-emitting laser; a light-intensity measuring unit configured to measure a light intensity of the at least one surface-emitting laser by receiving one split beam from the splitting unit; and a spectrum measuring unit configured to measure a spectrum of the at least one surface-emitting laser by receiving another split beam. Because the light intensity and the spectrum are simultaneously measured, the measurement time can be shortened.

(7) The splitting unit may be configured to split light at an emission wavelength of the at least one surface-emitting laser in a predetermined proportion. The light intensity and the spectrum can be accurately acquired based on the split proportion and the measurement results of the light intensity.

(8) The at least one surface-emitting laser may include a plurality of surface-emitting lasers arranged on a wafer, and the surface-emitting laser measuring apparatus may further include a temperature control unit configured to control a temperature of the wafer. Because the temperature control unit controls the temperature and the measurement time is shortened, less temperature change occurs. The change in the characteristics of the surface-emitting lasers with temperature change can be reduced.

(9) Another embodiment of the present disclosure is a non-transitory computer-readable medium having stored therein a program for causing a computer to execute a process, the process including the steps of causing at least one surface-emitting laser to emit light; and measuring a light intensity and a spectrum of the at least one surface-emitting laser using the light emitted from the at least one surface-emitting laser in the step of causing the at least one surface-emitting laser to emit light, the light being split and incident on a light-intensity measuring unit and a spectrum measuring unit. Because the light intensity and the spectrum are simultaneously measured, the measurement time can be shortened.

### Details of Embodiments of the Disclosure

A specific example of a surface-emitting laser measuring method, manufacturing method, measuring apparatus, and measuring program according to one embodiment of the present disclosure will hereinafter be described with reference to the drawings. It should be understood, however, that the disclosure is not limited to the illustrated example, but is indicated by the claims, and all changes that come within the meaning and range of equivalency of the claims are intended to be embraced therein.

### Measuring Apparatus

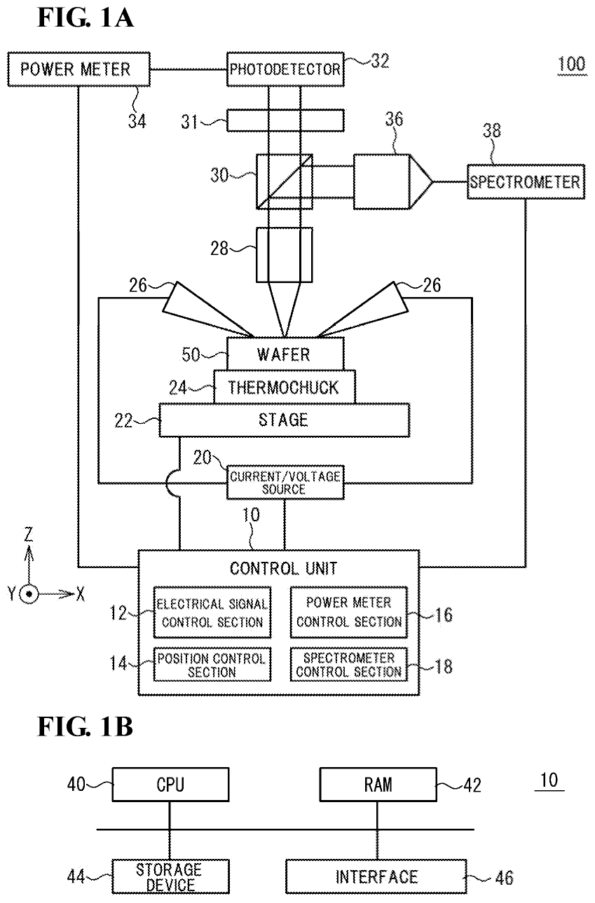

FIG. 1A is a schematic view illustrating an example measuring apparatus 100 according to one embodiment. As illustrated in FIG. 1A, the measuring apparatus 100 includes a control unit 10, a current/voltage source 20 (light-emission causing unit), a stage 22, a thermochuck 24 (temperature control unit), a pair of probes 26, lenses 28, 31, and 36, a beam splitter 30 (splitting unit), a photodetector 32, a power meter 34, and a spectrometer 38 (spectrum measuring unit). The X-axis direction, the Y-axis direction, and the Z-axis direction are orthogonal to each other.

The main surfaces of the stage 22, the thermochuck 24, and a wafer 50 are located in the XY-plane. The direction normal to these main surfaces is the Z-axis direction. The thermochuck 24 is mounted on the stage 22, and the wafer 50 is mounted on the thermochuck 24. The stage 22 is movable to change the position in the XY-plane and the height in the Z-axis direction of the thermochuck 24 and the wafer 50. The thermochuck 24 is a stage capable of temperature control and holds the wafer 50 by suction.

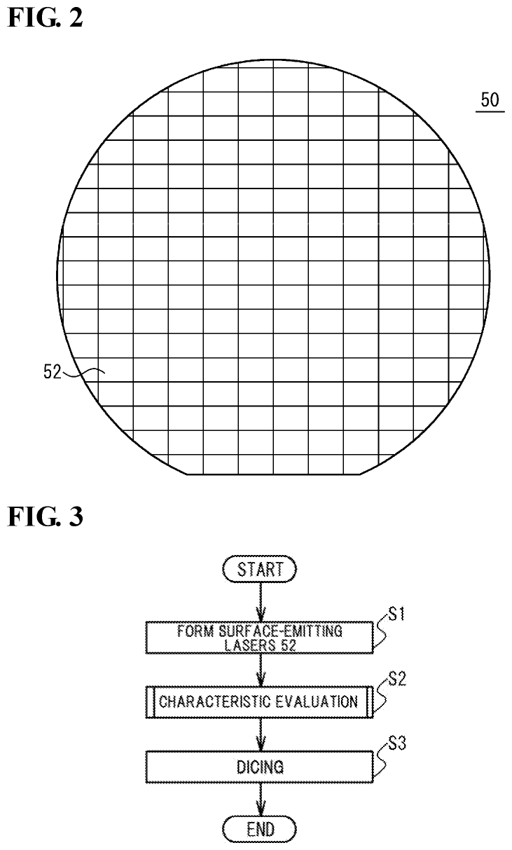

FIG. 2 is a plan view illustrating an example wafer 50. A plurality of surface-emitting lasers 52 are arranged in a two-dimensional grid on the wafer 50. For example, a 3 inch wafer 50 has 40,000 surface-emitting lasers 52. The surface-emitting lasers 52 are formed of, for example, compound semiconductors, and include a lower cladding layer, a core layer, and an upper cladding layer stacked together on the wafer 50. The wafer 50 is, for example, a semiconductor substrate formed of gallium arsenide (GaAs). The lower cladding layer and the upper cladding layer are formed of, for example, aluminum gallium arsenide (AlGaAs). The core layer is formed of, for example, indium gallium arsenide (InGaAs), and has a multi-quantum well (MQW) structure. When an electrical signal (current) is input to the surface-emitting lasers 52, they emit light with a wavelength of, for example, 800 nm to 1,000 nm in the Z-axis direction.

The current/voltage source 20 illustrated in FIG. 1A has a pair of probes 26 corresponding to n- and p-electrodes of the surface-emitting lasers 52. The probes 26 are formed of, for example, a metal, and is brought into contrast with pads (not illustrated) of the surface-emitting lasers 52. The current/voltage source 20 inputs an electrical signal (current) to the surface-emitting lasers 52 on the wafer 50 through the probes 26 to cause the surface-emitting lasers 52 to emit light. The current from the current/voltage source 20 can be changed. The current is changed stepwise, for example, in steps of 0.2 mA or 0.5 mA within the range of 0 to 10 mA.

The wafer 50, the lens 28, the beam splitter 30, the lens 31, and the photodetector 32 are arranged in sequence in the Z-axis direction. The beam splitter 30, the lens 36, and the spectrometer 38 are arranged in sequence in the X-axis direction.

The lens 28 is an objective lens. The lenses 31 and 36 are condenser lenses. The beam splitter 30 is, for example, a cube with a side length of 25 mm to 50 mm, and splits light in the Z-axis direction and the X-axis direction. The proportion in which the beam splitter 30 splits light is determined by the wavelength of the light. For example, the beam splitter 30 splits light at the emission wavelength of the surface-emitting lasers 52 in a proportion of 1:1. The photodetector 32 and the power meter 34 function as a light-intensity measuring unit. The photodetector 32 includes, for example, a photodiode or an integrating sphere, and receives light to output an electrical signal. The power meter 34 is electrically connected to the photodetector 32 and determines the light intensity based on the electrical signal input from the photodetector 32. The lens 36 is coupled to the spectrometer 38, for example, with an optical fiber. The spectrometer 38 measures the spectrum of the input light.

Light emitted from the surface-emitting lasers 52 on the wafer 50 propagates through the lens 28 into the beam splitter 3, which splits the light. One split beam propagates from the beam splitter 30 in the Z-axis direction and is focused onto the photodetector 32 by the lens 31. The other beam propagates from the beam splitter 30 in the X-axis direction and is focused onto the spectrometer 38 by the lens 36. Because the light is split, the light intensity and the spectrum can be simultaneously measured.

The control unit 10 is, for example, a control device such as a personal computer, and is electrically connected to the current/voltage source 20, the stage 22, the power meter 34, and the spectrometer 38.

FIG. 1B is a block diagram illustrating the hardware configuration of the control unit 10. As illustrated in FIG. 1B, the control unit 10 includes a central processing unit (CPU) 40, a random-access memory (RAM) 42, a storage device 44, and an interface 46. The CPU 40, the RAM 42, the storage device 44, and the interface 46 are connected to each other, for example, via a bus. The RAM 42 is a volatile memory for temporarily storing, for example, programs and data. The storage device 44 is, for example, a read-only memory (ROM), a solid-state drive (SSD) such as a flash memory, or a hard disc drive (HDD). The storage device 44 stores, for example, a measuring program described later.

The CPU 40 executes the programs stored in the RAM 42 to implement various sections in the control unit 10, such as an electrical signal control section 12, a position control section 14, a power meter control section 16, and a spectrometer control section 18 in FIG. 1A. The various sections of the control unit 10 may also be implemented by hardware such as circuitry. The electrical signal control section 12 controls the current/voltage source 20, for example, to switch on and off the current input to the wafer 50 and change the current. The position control section 14 controls the stage 22 to adjust the position of the wafer 50. The power meter control section 16 controls the power meter 34 to acquire the light intensity from the power meter 34. The spectrometer control section 18 controls the spectrometer 38 to acquire the spectrum from the spectrometer 38.

### Manufacturing Method and Measuring Method

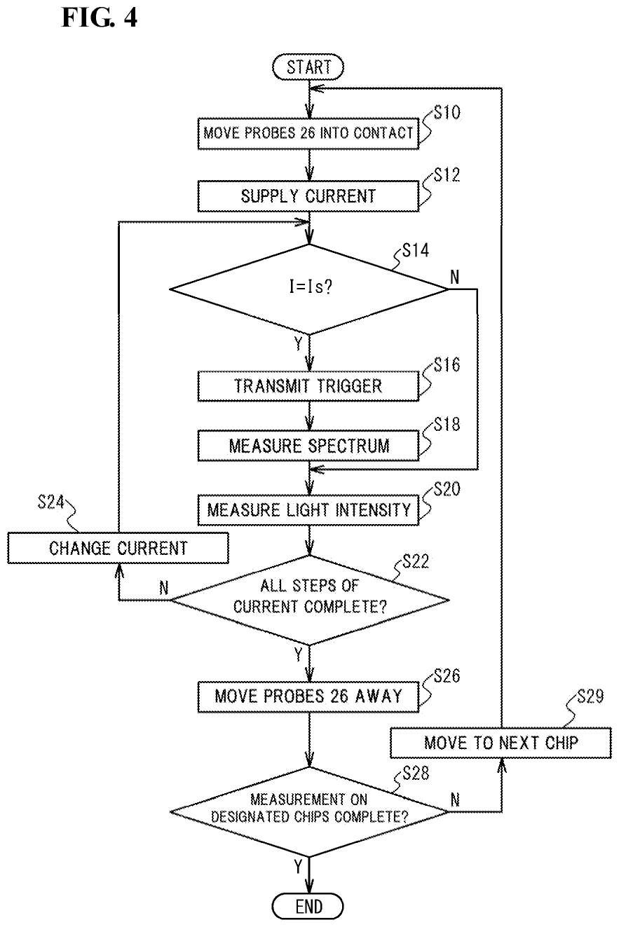

FIG. 3 is a flowchart illustrating an example surface-emitting laser manufacturing method. As illustrated in FIG. 3, a plurality of surface-emitting lasers 52 are formed on the wafer 50 (step Si). Specifically, for example, a lower cladding layer, a core layer, and an upper cladding layer are epitaxially grown on the wafer 50 by metal organic chemical vapor deposition (MOCVD). A mesa serving as a light emitting portion is formed, for example, by etching. Electrodes are formed, for example, by resist patterning and evaporation. After the surface-emitting lasers 52 are formed, the characteristics of the surface-emitting lasers 52 are evaluated (step S2, FIG. 4). After the evaluation, the wafer 50 is diced (step S3).

The characteristic evaluation will now be described in detail. FIG. 4 is a flowchart illustrating an example characteristic measuring method, which is performed in step S2 in FIG. 3. One of the surface-emitting lasers 52 on the wafer 50 is aligned to the lens 28 and the beam splitter 30 in advance. The distance between the lens 28 and the surface-emitting laser 52 is, for example, 5 cm. As illustrated in FIG. 4, the current/voltage source 20 causes the probes 26 to be moved into contact with the electrodes of the surface-emitting laser 52 (step S10). The current/voltage source 20 supplies a current through the probes 26 to the surface-emitting laser 52, thereby inputting an electrical signal (current) (step S12). As the current is input, the surface-emitting laser 52 emits light. As illustrated in FIG. 1A, the beam splitter 30 splits the light in the X-axis direction and the Z-axis direction. The split beams are incident on the photodetector 32 and the spectrometer 38.

The control unit 10 determines whether the current I input to the surface-emitting laser 52 is equal to a predetermined current Is (step S14). If no, the spectrometer control section 18 blocks a trigger from the current/voltage source 20 to the spectrometer 38. No trigger is input to the spectrometer 38, and no spectrum measurement is performed. The photodetector 32 and the power meter 34 measure the light intensity (step S20). The electrical signal control section 12 determines whether all steps of the current are complete (step S22). If no, the electrical signal control section 12 changes the current, for example, by 0.2 mA (step S24). Thereafter, step S14 is performed again. The electrical signal control section 12 changes the current stepwise, for example, in steps of 0.2 mA within the range of 0 to 10 mA.

If the current I is equal to the predetermined current Is (yes in step S14), the current/voltage source 20 transmits a trigger, and the spectrometer control section 18 does not block the trigger (step S16). In response to the trigger, the spectrometer 38 measures the spectrum (step S18). Concurrently with the spectrum measurement, the photodetector 32 and the power meter 34 measure the light intensity (step S20).

If the control unit 10 determines that all steps of the current, for example, within the range of 0 to 10 mA, are complete (yes in step S22), the current/voltage source 20 causes the probes 26 to be moved away from the surface-emitting laser 52 (step S26). The control unit 10 determines whether the measurement on the surface-emitting lasers 52 designated for measurement (designated chips) on the wafer 50 is complete (step S28). For example, all of the plurality of surface-emitting lasers 52 on the wafer 50, half of the chips, 60% of the chips, or 80% of the chips may be designated for measurement.

If no, the stage 22 moves the wafer 50 to position the next chip (surface-emitting laser 52) under the lens 28 and the beam splitter 30 (step S29). Step S10 and the subsequent steps are performed on that chip. The measurement ends when the measurement on the surface-emitting lasers 52 designated for measurement on the wafer 50 is complete (yes in step S28).

As illustrated in FIG. 3, dicing is performed after the characteristic measurement (step S3). Chips including a single surface-emitting laser 52 or array chips including a plurality of surface-emitting lasers 52 may be formed.

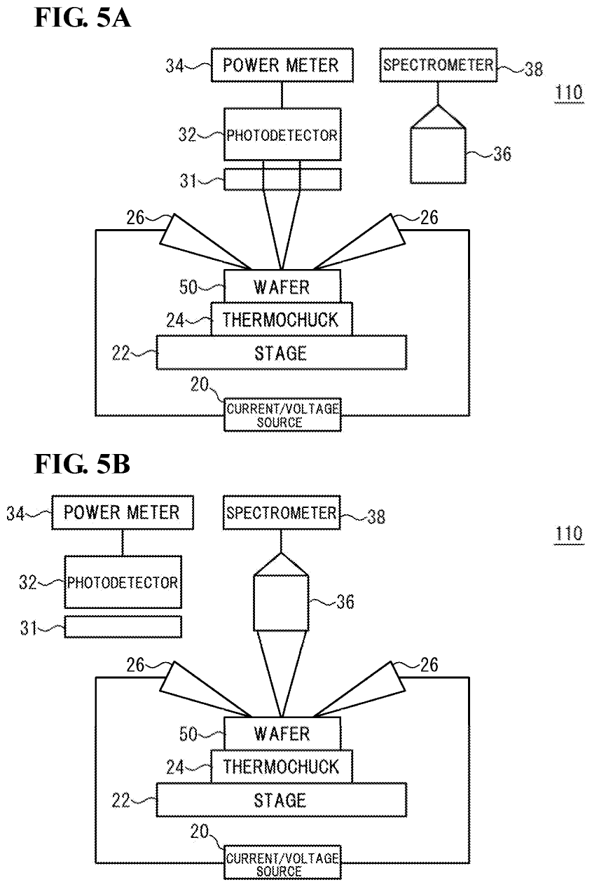

FIGS. 5A and 5B are schematic views illustrating an example measuring apparatus 110 according to a comparative example. The measuring apparatus 110 does not include the beam splitter 30. In the example in FIG. 5A, the lens 31 and the photodetector 32 are positioned over the wafer 50 so that the photodetector 32 can receive light. The spectrometer 38 does not receive light because the lens 36 is not aligned to the wafer 50. In the example in FIG. 5B, the lens 36 is positioned over the wafer 50 so that the spectrometer 38 receives light. The photodetector 32 is not aligned to the wafer 50 and therefore does not receive light.

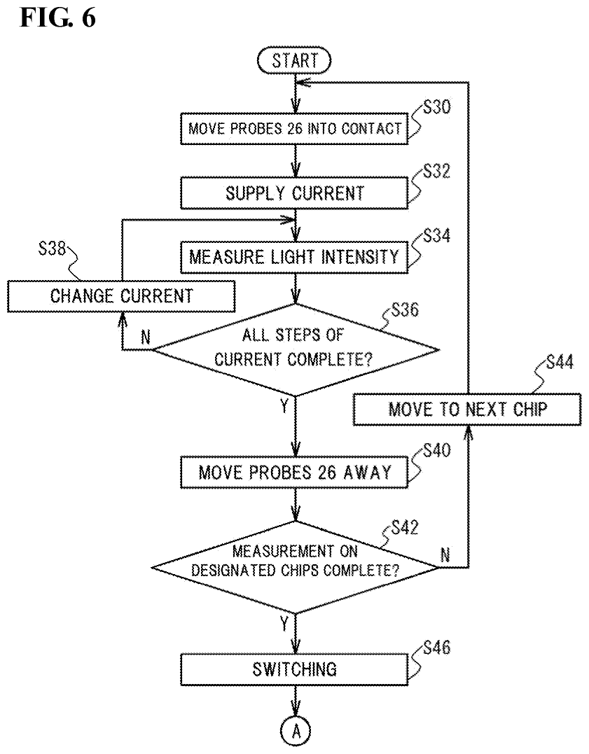

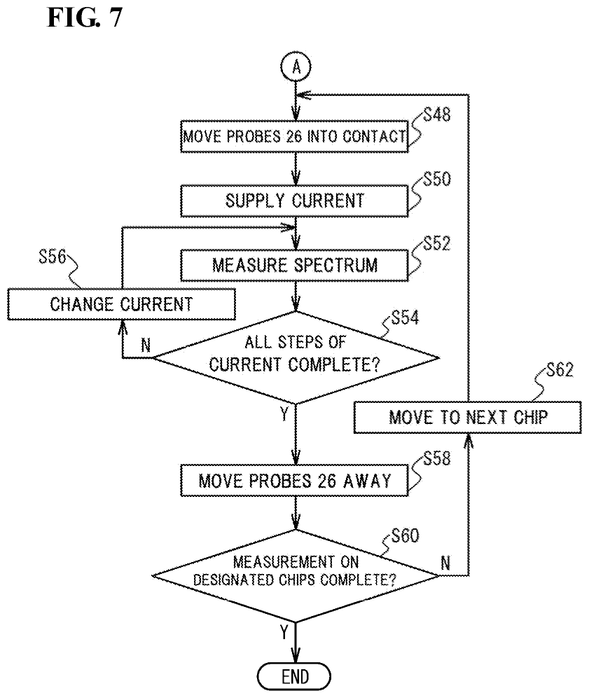

FIGS. 6 and 7 are flowcharts illustrating an example measuring method in the comparative example. Step S30 in FIG. 6 and step S48 in FIG. 7 are identical to step S10 in FIG. 4. Steps S32 and S50 are identical to step S12. Steps S36 and S54 are identical to step S22. Steps S38 and S56 are identical to step S24. Steps S40 and S58 identical to step S26. Steps S42 and S60 are identical to step S28. Steps S44 and S62 are identical to step S29. Step S34 in FIG. 6 is identical to step S20, i.e., a light intensity measurement step. Step S52 in FIG. 7 is identical to step S18, i.e., a spectrum measurement step.

In the steps in FIG. 6, as illustrated in FIG. 5A, the lens 31 and the photodetector 32 are positioned over the wafer 50. In steps S30 to S42 in FIG. 6, a current is input to the designated chips on the wafer 50, and the light intensity of the surface-emitting lasers 52 is measured. Thereafter, switching is made from the configuration in FIG. 5A to the configuration in FIG. 5B so that the lens 36 and the spectrometer 38 are positioned over the wafer 50 (step S46). In steps S48 to S60 in FIG. 7, a current is input to the designated chips on the wafer 50, and the spectrum of the surface-emitting lasers 52 is measured.

As illustrated in FIGS. 6 and 7, the light intensity and the spectrum are measured in different processes in the comparative example. The measurement takes time because the movement of the probes 26 into contact with and away from the designated chips and the movement to the next chip are repeated in each of the light intensity measurement and the spectrum measurement.

In contrast, according to the present embodiment, the beam splitter 30 splits light emitted from the surface-emitting lasers 52. The split beams are incident on the photodetector 32 and the spectrometer 38, thereby measuring the light intensity and the spectrum. Because the light intensity and the spectrum are simultaneously measured, the measurement time can be shortened compared to the sequential measurement as in the comparative example.

As illustrated in FIG. 2, the plurality of surface-emitting lasers 52 are arranged on the wafer 50. After the light intensity and spectrum of one surface-emitting laser 52 are measured, the light intensity and spectrum of another surface-emitting laser 52 are measured. That is, the light intensity and the spectrum are simultaneously measured for each of the plurality of surface-emitting lasers 52. This considerably shortens the measurement time compared to the sequential measurement of the light intensity and spectrum of the plurality of surface-emitting lasers 52 as in the comparative example. The wafer 50 has, for example, 10,000 or more surface-emitting lasers 52. As one example, a 3 inch wafer 50 has 40,000 surface-emitting lasers 52. Because the light intensity and the spectrum are simultaneously measured for many surface-emitting lasers 52, for example, 10,000 or more surface-emitting lasers 52, the measurement time is considerably shortened. As illustrated in FIG. 3, by performing the measurement after forming the plurality of surface-emitting lasers 52 on the wafer 50 and before dicing the wafer 50, inspection can be performed within a short period of time during the manufacturing process.

The optical system used for measurement, including the beam splitter 30, the lenses 28, 31, and 36, the photodetector 32, and the spectrometer 38, is positioned over one surface-emitting laser 52 designated for measurement, and the light intensity and the spectrum are measured. Thereafter, the wafer 50 is moved to align another surface-emitting laser 52 designated for measurement to the optical system. Because the number of times of alignment is decreased, the measurement time can be shortened. The effort required for adjustments such as lens focusing is also halved. Because the number of times the pair of probes 26 are moved into contact with and away from the surface-emitting lasers 52 is also decreased, the measurement time is halved.

Because it is sufficient to add the beam splitter 30 to the photodetector 32, the power meter 34, and the spectrometer 38, there is no significant cost increase. The beam splitter 30 splits light at the emission wavelength of the surface-emitting lasers 52 in a predetermined proportion. The control unit 10 can acquire the accurate light intensity and spectrum based on the split proportion and the measurement results. The split proportion need not be 1:1. The spectrometer 38 may be replaced with, for example, a spectrum analyzer.

When the current/voltage source 20 inputs a current to the surface-emitting lasers 52, they emit light. When the current is changed and reaches a predetermined level, the light intensity and the spectrum are measured. The current is changed stepwise, for example, in steps of 0.2 mA within the range of 0 to 10 mA. The light intensity at each current can be measured by performing an LIV test for measuring light intensity while changing the current. The light intensity may be measured at all steps of the current or may be measured at certain steps. For example, when the current reaches a predetermined level Is, the spectrum is measured. If the current Is is set to, for example, 8 mA, which is similar to the current through the surface-emitting lasers 52 during actual use, a spectrum with high accuracy can be obtained. The spectrum may be measured at a plurality of currents. The range and step size of the current may be changed.

The characteristics of the surface-emitting lasers 52 may change with temperature change. The thermochuck 24 illustrated in FIG. 1A controls the temperature of the wafer 50. According to the embodiment, the measurement time is halved compared to the comparative example; therefore, the temperature of the wafer 50 changes to a lesser extent. This reduces the change in the characteristics of the surface-emitting lasers 52 with temperature change and thus allows for measurements with high accuracy.

Although one embodiment of the present disclosure has been described in detail above, the disclosure is not limited to the specific embodiment. Rather, various changes and modifications can be made within the spirit of the disclosure as set forth in the claims.

What is claimed is:

1. A surface-emitting laser measuring method comprising the steps of:
causing at least one surface-emitting laser to emit light; and
measuring a light intensity and a spectrum of the at least one surface-emitting laser by splitting the light emitted from the at least one surface-emitting laser in the step of causing the at least one surface-emitting laser to emit light and causing one split beam to be incident on a light-intensity measuring unit while causing another split beam to be incident on a spectrum measuring unit.

2. The surface-emitting laser measuring method according to claim 1,
wherein the at least one surface-emitting laser comprises a plurality of surface-emitting lasers arranged on a wafer, the plurality of surface-emitting lasers including a first surface-emitting laser and a second surface-emitting laser, and
after the first surface-emitting laser is subjected to the step of causing light emission and the step of measuring the light intensity and the spectrum, the second surface-emitting laser is subjected to the step of causing light emission and the step of measuring the light intensity and the spectrum.

3. The surface-emitting laser measuring method according to claim 2, further comprising the steps of:
positioning a splitting unit configured to split the light over the first surface-emitting laser; and
after the step of measuring the light intensity and the spectrum of the first surface-emitting laser, positioning the splitting unit over the second surface-emitting laser,
wherein the step of measuring the light intensity and the spectrum comprises measuring the light intensity and the spectrum by causing one split beam from the splitting unit to be incident on the light-intensity measuring unit while causing another split beam to be incident on the spectrum measuring unit.

4. The surface-emitting laser measuring method according to claim 1, wherein
the step of causing the at least one surface-emitting laser to emit light comprises changing an amplitude of electrical signals input to the at least one surface-emitting laser to cause the at least one surface-emitting laser to emit light for each of the electrical signals with different amplitudes, and
the step of measuring the light intensity and the spectrum of the at least one surface-emitting laser comprises measuring the light intensity and the spectrum when the amplitude of the electrical signals reaches a predetermined level.

5. A surface-emitting laser manufacturing method comprising the steps of:
forming a plurality of surface-emitting lasers on a wafer; and
subjecting the plurality of surface-emitting lasers to the measuring method according to claim 1.

6. A surface-emitting laser measuring apparatus comprising:
a light-emission causing unit configured to cause at least one surface-emitting laser to emit light;
a splitting unit configured to split the light emitted from the at least one surface-emitting laser;
a light-intensity measuring unit configured to measure a light intensity of the at least one surface-emitting laser by receiving one split beam from the splitting unit; and
a spectrum measuring unit configured to measure a spectrum of the at least one surface-emitting laser by receiving another split beam.

7. The surface-emitting laser measuring apparatus according to claim 6, wherein the splitting unit is configured to split light at an emission wavelength of the at least one surface-emitting laser in a predetermined proportion.

8. The surface-emitting laser measuring apparatus according to claim 6,
wherein the at least one surface-emitting laser comprises a plurality of surface-emitting lasers arranged on a wafer,
the surface-emitting laser measuring apparatus further comprising a temperature control unit configured to control a temperature of the wafer.

9. A non-transitory computer-readable medium having stored therein a program for causing a computer to execute a process, the process comprising the steps of:
causing at least one surface-emitting laser to emit light; and
measuring a light intensity and a spectrum of the at least one surface-emitting laser using the light emitted from the at least one surface-emitting laser in the step of causing the at least one surface-emitting laser to emit light, the light being split and incident on a light-intensity measuring unit and a spectrum measuring unit.
